(19) United States
(12) Patent Application Publication
(10) Pub. No.: US 2009/0205709 A1
(43) Pub. Date: Aug. 20, 2009

(54) Thin film type solar cell and method for manufacturing the same

(76) Inventor: Jae Ho KIM, Yongin-si (KR)

Correspondence Address: Royal W. Craig;Ober, Kaler, Grimes & Shriver, 120 East Baltimore Street, Baltimore, MD, 21202-1643, US

(21) Appl. No.: 12/378,890

(22) Filed: Feb. 20, 2009

(30) Foreign Application Priority Data
Feb. 20, 2008 (KR) 10-2008-0015124

(51) Int. Cl. H01L 31/00; B05D 5/12; C23C 14/34

(52) U.S. Cl. 136/256; 427/74; 204/192.15

(57) ABSTRACT

A thin film type solar cell and a method for manufacturing the same is disclosed, the thin film type solar cell comprising a front electrode formed on a substrate; a semiconductor layer formed on the front electrode; a transparent conductive layer formed on the semiconductor layer; a rear electrode formed over the transparent conductive layer; and a buffer layer, formed between the transparent conductive layer and the rear electrode, for reducing an electric resistance of the rear electrode and enhancing an adhesive strength between the transparent conductive layer and the rear electrode.

### CROSS REFERENCE TO RELATED APPLICATIONS

This application claims the benefit of the Korean Patent Application No. P2008-0015124, filed on Feb. 20, 2008, which is hereby incorporated by reference as if fully set forth herein.

### BACKGROUND OF THE INVENTION

1. Field of the Invention

The present invention relates to a solar cell, and more particularly, to a thin film type solar cell.

2. Discussion of the Related Art

A solar cell with a property of semiconductor converts light energy into an electric energy.

A structure and principle of the solar cell according to the related art will be briefly explained as follows. The solar cell is formed in a PN-junction structure where a positive (P)-type semiconductor makes a junction with a negative (N)-type semiconductor. When a solar ray is incident on the solar cell with the PN-junction structure, holes (+) and electrons (−) are generated in the semiconductor owing to the energy of the solar ray. By an electric field generated in a PN-junction area, the holes (+) are drifted toward the P-type semiconductor, and the electrons (−) are drifted toward the N-type semiconductor, whereby an electric power is produced with an occurrence of electric potential.

The solar cell can be largely classified into a wafer type solar cell and a thin film type solar cell.

The wafer type solar cell uses a wafer made of a semiconductor material such as silicon. In the meantime, the thin film type solar cell is manufactured by forming a semiconductor in type of a thin film on a glass substrate.

With respect to efficiency, the wafer type solar cell is better than the thin film type solar cell. However, in the case of the wafer type solar cell, it is difficult to realize a small thickness due to difficulty in performance of the manufacturing process. In addition, the wafer type solar cell uses a high-priced semiconductor substrate, whereby its manufacturing cost is increased.

Even though the thin film type solar cell is inferior in efficiency to the wafer type solar cell, the thin film type solar cell has advantages such as realization of thin profile and use of low-priced material. Accordingly, the thin film type solar cell is suitable for a mass production.

The thin film type solar cell is manufactured by sequential steps of forming a front electrode on a glass substrate, forming a semiconductor layer on the front electrode, and forming a rear electrode on the semiconductor layer.

Hereinafter, a method for manufacturing a thin film type solar cell according to the related art will be described with reference to the accompanying drawings.

FIG. 1(A to D) is a series of cross section views illustrating a related method for manufacturing a thin film type solar cell.

First, as shown in FIG. 1(A), a front electrode 20 is formed on a substrate 10.

Next, as shown in FIG. 1(B), a semiconductor layer 30 is formed on the front electrode 20.

Then, as shown in FIG. 1(C), a transparent conductive layer 40 is formed on the semiconductor layer 30.

Then, as shown in FIG. 1(D), a rear electrode 60 is formed on the transparent conductive layer 40.

At this time, the rear electrode 60 is formed by printing a metal material such as aluminum (Al) or silver (Ag) on the transparent conductive layer 40, and carrying out a baking process at a predetermined temperature. During the baking process, the metal material such as Al or Ag for the rear electrode 60 is oxidized so that a rear electrode oxide 65 is formed between the rear electrode 60 and the transparent conductive layer 40.

The rear electrode oxide 65 may be comprised of aluminum oxide or silver oxide. However, a high resistance value of the aluminum oxide or silver oxide may cause the increase of resistance in the rear electrode 60, thereby lowering the efficiency of solar cell.

### SUMMARY OF THE INVENTION

Accordingly, the present invention is directed to a thin film type solar cell and a method for manufacturing the same that substantially obviates one or more problems due to limitations and disadvantages of the related art.

An object of the present invention is to provide a thin film type solar cell and a method for manufacturing the same, wherein a buffer layer is formed between a rear electrode and a transparent conductive layer so as to prevent the formation of an oxide of the rear electrode, thereby improving the efficiency of solar cell.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a thin film type solar cell comprises a front electrode formed on a substrate; a semiconductor layer formed on the front electrode; a transparent conductive layer formed on the semiconductor layer; a rear electrode formed over the transparent conductive layer; and a buffer layer, formed between the transparent conductive layer and the rear electrode, for reducing an electric resistance of the rear electrode and enhancing an adhesive strength between the transparent conductive layer and the rear electrode.

In another aspect of the present invention, a method for manufacturing a thin film type solar cell comprises forming a front electrode on a substrate; forming a semiconductor layer on the front electrode; forming a transparent conductive layer on the semiconductor layer; forming a buffer layer on the transparent conductive layer; and forming a rear electrode on the buffer layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1(A to D) is a series of cross section views illustrating a related method for manufacturing a thin film type solar cell;

FIG. 2 is a cross section view illustrating a thin film type solar cell according to one embodiment of the present invention;

FIG. 3(A to F) is a series of cross section views illustrating a method for manufacturing a thin film type solar cell according to one embodiment of the present invention; and

FIG. 4(A to F) is a series of cross section views illustrating a method for manufacturing a thin film type solar cell according to another embodiment of the present invention.

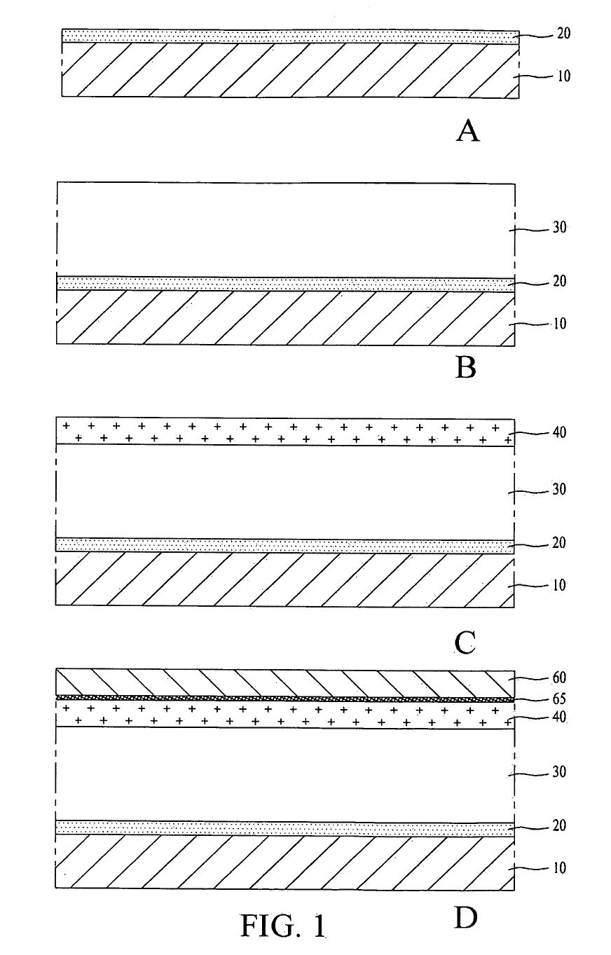

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a thin film type solar cell according to the present invention and a method for manufacturing the same will be described with reference to the accompanying drawings.

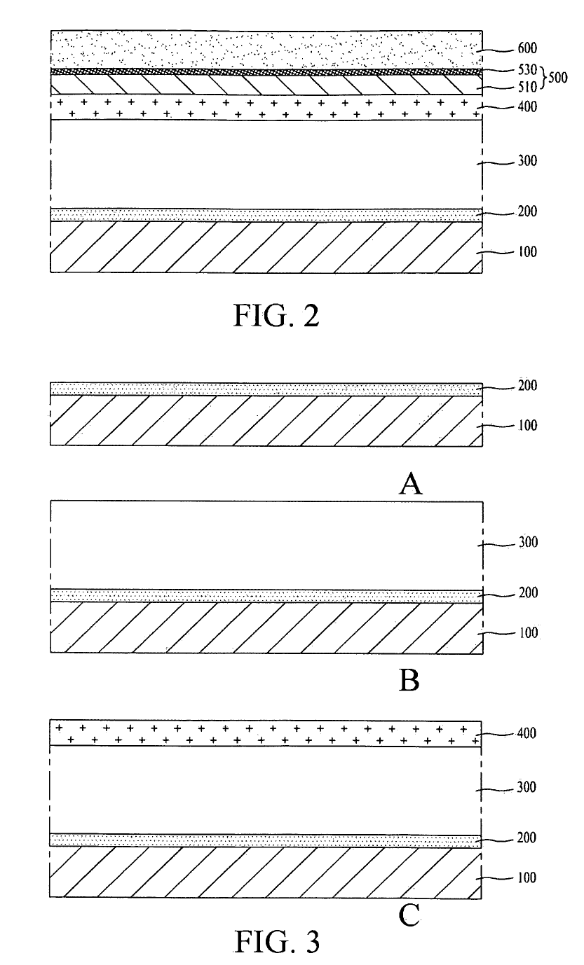

FIG. 2 is a cross section view illustrating a thin film type solar cell according to one embodiment of the present invention.

As shown in FIG. 2, the thin film type solar cell according to one embodiment of the present invention includes a substrate 100, a front electrode 200, a semiconductor layer 300, a transparent conductive layer 400, a buffer layer 500, and a rear electrode 600.

The substrate 100 is formed of glass or transparent plastic.

The front electrode 200 may be formed of a transparent conductive material, for example, ZnO, ZnO:B, ZnO:Al, ZnO:H, SnO₂, SnO₂:F, or ITO (Indium Tin Oxide).

Preferably, the front electrode 200 has an uneven surface through a texturing process. Through the texturing process, a surface of material layer is provided with an uneven surface, that is, a texture structure, by an etching process using photolithography, an anisotropic etching process using a chemical solution, or a mechanical scribing process. According as the texturing process is performed to the front electrode 200, a solar-ray reflection ratio on the solar cell is decreased and a solar-ray absorbing ratio on the solar cell is increased owing to a dispersion of the solar ray, thereby improving the solar cell efficiency.

The semiconductor layer 300 is formed of a silicon-based semiconductor material.

The semiconductor layer 300 is formed in a PIN structure where a P-type semiconductor layer, an I-type semiconductor layer, and an N-type semiconductor layer are deposited in sequence. In the semiconductor layer 300 with the PIN structure, depletion is generated in the I-type semiconductor layer by the P-type semiconductor layer and the N-type semiconductor layer, whereby an electric field occurs therein. Thus, electrons and holes generated by the solar ray are drifted by the electric field, and the drifted electrons and holes are collected in the N-type semiconductor layer and the P-type semiconductor layer.

For formation of the semiconductor layer 300 in the PIN structure, the P-type semiconductor layer is formed firstly, and then the I-type and N-type semiconductor layers are formed thereon, preferably. This is because a drift mobility of the hole is less than a drift mobility of the electron. In order to maximize the efficiency in collection of the incident light, the P-type semiconductor layer is provided adjacent to the light-incidence face.

The transparent conductive layer 400 is formed of a transparent conductive material such as ZnO.

The transparent conductive layer 400 makes the solar ray dispersed in all angles, whereby the solar ray is reflected on a rear electrode to be described, thereby resulting in the increase of solar ray re-incidence on the semiconductor layer 300.

The buffer layer 500 is formed between the transparent conductive layer 400 and the rear electrode 600, wherein the buffer layer 500 can reduce an electric resistance of the rear electrode 600, and also can enhance an adhesive strength between the transparent conductive layer 400 and the rear electrode 600.

The buffer layer 500 is formed of a material whose oxidization degree is higher than that of a material for the rear electrode 600. Preferably, the buffer layer 500 comprises a transparent metal layer 510 such as Zn. Thus, an oxide layer 530 of ZnO is formed as an oxide of the transparent metal layer 510 during a baking process for forming the rear electrode 600. In comparison to aluminum oxide or silver oxide with large electric resistance in the related art thin film type solar cell, an electric resistance of the oxide layer 530 of ZnO is remarkably small.

Accordingly, as the buffer layer 500 comprises the metal layer 510 of Zn and the oxide layer 530 of ZnO in sequence, the electric resistance of the rear electrode 600 is reduced so that the efficiency of the solar cell improves. Also, the oxide layer 530 comprised in the buffer layer 500 can enhance the adhesive strength between the transparent conductive layer 400 and the rear electrode 600.

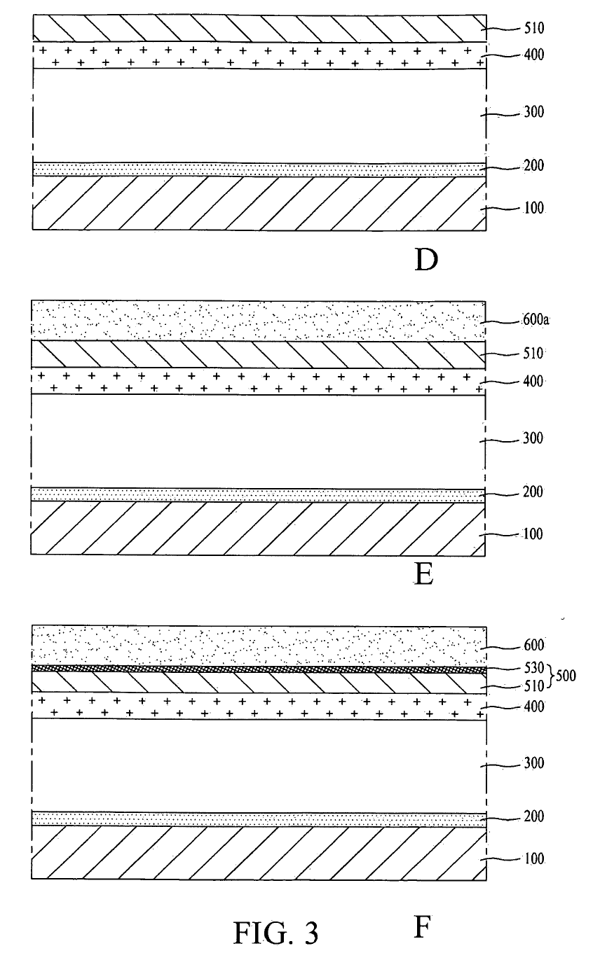

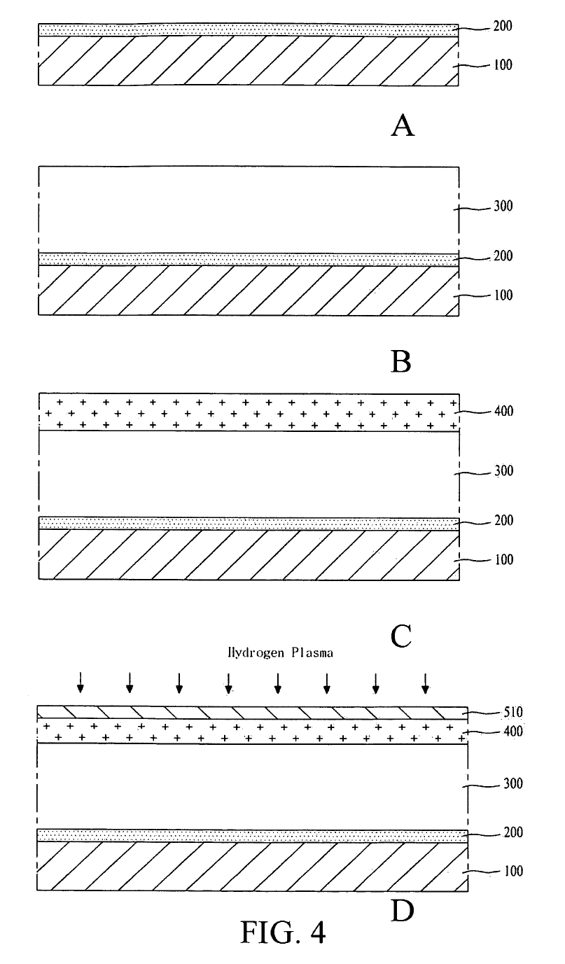

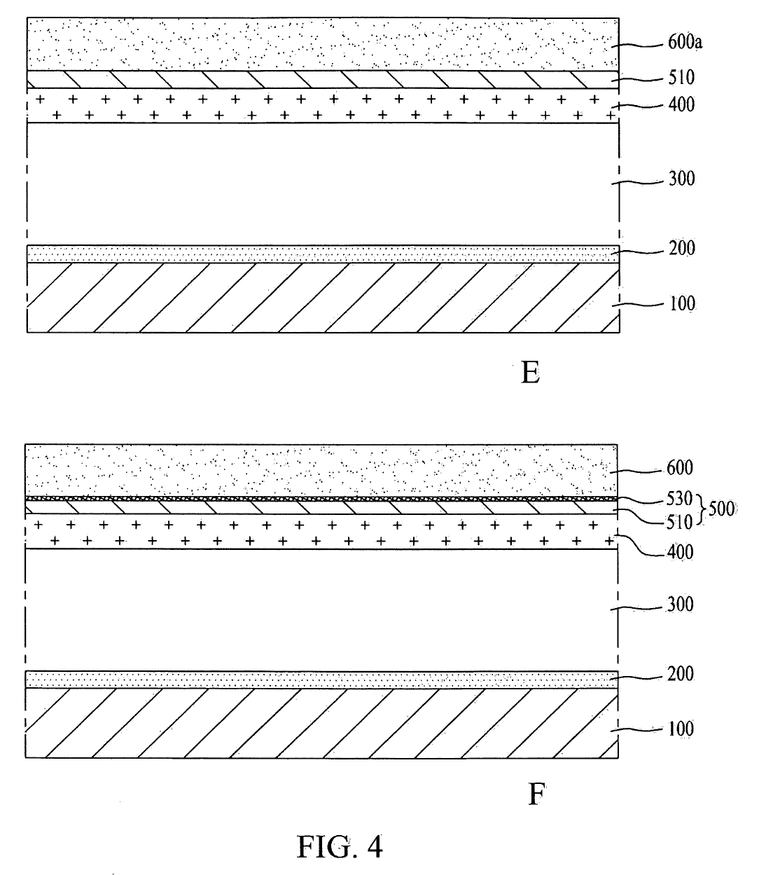

The transparent conductive layer 400 is formed of ZnO, the metal layer 510 of the buffer layer 500 is formed of Zn, and the oxide layer 530 of the buffer layer 500 is formed of ZnO. Accordingly, as both the oxide layer 530 comprised in the buffer layer 500 and the transparent conductive layer 400 are formed of the same material, continuous processes may be performed in the same apparatus (see FIG. 3 A to F), or the metal layer 510 comprised in the buffer layer 500 may be formed through the use of transparent conductive layer 400 (see FIG. 4A to F), thereby resulting in easy and simple control of process. This can be understood by a following method for manufacturing the thin film type solar cell according to the present invention.

The rear electrode 600 is formed of a metal material, for example, Ag, Al, Ag+Mo, Ag+Ni, or Ag+Cu.

FIG. 3(A to F) is a series of cross section views illustrating a method for manufacturing a thin film type solar cell according to one embodiment of the present invention.

First, as shown in FIG. 3(A), a front electrode 200 is formed on a substrate 100.

The front electrode 200 may be formed of a transparent conductive material, for example, ZnO, ZnO:B, ZnO:Al, ZnO:H, SnO₂, SnO₂:F, or ITO (Indium Tin Oxide) by sputtering or MOCVD (Metal Organic Chemical Vapor Deposition).

In order to maximize solar-ray absorbing efficiency, the front electrode 200 may have an uneven surface through a texturing process.

Next, as shown in FIG. 3(B), a semiconductor layer 300 is formed on the front electrode 200.

The semiconductor layer 300 may be formed of a silicon-based semiconductor material by a plasma CVD method, wherein the semiconductor layer 300 is formed in a PIN structure where a P-type semiconductor layer, an I-type semiconductor layer, and an N-type semiconductor layer are deposited in sequence.

As shown in FIG. 3(C), a transparent conductive layer 400 is formed on the semiconductor layer 300.

The transparent conductive layer 400 may be formed of a transparent conductive material such as ZnO by sputtering or MOCVD.

As shown in FIG. 3(D), a metal layer 510 is formed on the transparent conductive layer 400. The metal layer 510 is formed of a metal material whose oxidization degree is higher than that of a material for a rear electrode to be described. Accordingly, instead of an oxide of the rear electrode, an oxide layer of the metal layer 510 is formed during a baking process for forming the rear electrode.

The metal layer 510 is formed by depositing an additional layer on the transparent conductive layer 400, which can be formed by sputtering, CVD (Chemical Vapor Deposition), or ALD (Atomic Layer Deposition).

First, the metal layer 510 may be formed on the transparent conductive layer 400 by sputtering. This enables continuous processes in the same sputtering apparatus for carrying out the process of FIG. 3(C). That is, the transparent conductive layer 400 of ZnO is formed by sputtering process targeting Zn under an oxygen atmosphere as shown in FIG. 3C, and the metal layer 510 is formed by sputtering process targeting Zn under an inert-gas atmosphere such as Argon as shown in FIG. 3(D). Accordingly, the processes of FIG. 3(C) and FIG. 3(D) can be continuously carried out only by changing the kind of gas supplied to the same sputtering apparatus.

Second, the metal layer 510 may be formed on the transparent conductive layer 400 by CVD or ALD. In detail, the metal layer 510 of Zn may be formed by CVD or ALD using Zn(CH₃)₂ or Zn(C₂H₅)₂ under a hydrogen-gas atmosphere. In this case, the metal layer 510 of Zn is formed through a reaction of ‘Zn(CH₃)₂+H₂→Zn+2(CH₄)’ or ‘Zn(C₂H₅)₂+H₂→Zn+2(C₂H₆)’.

Next, as shown in FIG. 3(E), a rear electrode material layer 600a is formed on the metal layer 510.

The rear electrode material layer 600a may be formed of a metal material, for example, Ag, Al, Ag+Al, Ag+Mg, Ag+Mn, Ag+Sb, Ag+Zn, Ag+Mo, Ag+Ni, Ag+Cu, or Ag+Al+Zn by a screen printing method, an inkjet printing method, a gravure printing method, or a micro-contact printing method.

As shown in FIG. 3(F), the rear electrode 600 is formed by baking the rear electrode material layer 600a.

When baking the rear electrode material layer 600a, the upper portion of the metal layer 510 is oxidized so that an oxide layer 530 of the metal layer 510 is formed therein. Thus, the buffer layer 500 is completed, which is comprised of the metal layer 510 and the oxide layer 530.

That is, an oxidization degree of the metal layer 510 is higher than an oxidization degree of the rear electrode material layer 600a. In this reason, instead of an oxide of the rear electrode material layer 600a, the oxide layer 530 of the metal layer 510 is formed during the baking process. If the metal layer 510 is formed of Zn, the oxide layer 530 of the metal layer 510 is formed of ZnO. In comparison to an electric resistance of an oxide of a rear electrode in the related art thin film type solar cell, an electric resistance of the oxide layer 530 of the metal layer 510 in the thin film type solar cell according to the present invention is remarkably lower, thereby preventing resistance of the rear electrode 600 from being increased. Also, an adhesive strength between the rear electrode 600 and the transparent conductive layer 400 is largely enhanced by the oxide layer 530 generated during the baking process.

FIG. 4(A to F) is a series of cross section views illustrating a method for manufacturing a thin film type solar cell according to another embodiment of the present invention.

Except that a metal layer 510 is formed by deoxidizing an upper portion of a transparent conductive layer 400 instead of depositing an additional layer on the transparent conductive layer 400, the method illustrated in FIG. 4(A to F) is identical to the method illustrated in FIG. 3(A to F). Thus, the detailed explanation for the same or like parts will be omitted.

First, as shown in FIG. 4(A), a front electrode 200 is formed on a substrate 100.

Next, as shown in FIG. 4(B), a semiconductor layer 300 is formed on the front electrode 200.

As shown in FIG. 4(C), the transparent conductive layer 400 is formed on the semiconductor layer 300.

The transparent conductive layer 400 may be formed of a transparent conductive material such as ZnO by sputtering or MOCVD.

Next, as shown in FIG. 4(D), the metal layer 510 is formed by deoxidizing the upper portion of the transparent conductive layer 400.

That is, if a hydrogen plasma treatment is applied to the transparent conductive layer 400, oxygen (O₂) contained in the transparent conductive layer 400 reacts with hydrogen (H₂) supplied for the hydrogen plasma treatment at the upper portion of the transparent conductive layer 400. When oxygen (O₂) escapes from the transparent conductive layer 400, the upper portion of the transparent conductive layer 400 becomes the metal layer 510 by deoxidization. For example, if the hydrogen plasma treatment is performed to ZnO contained in the transparent conductive layer 400, the metal layer 510 of Zn is formed at the upper portion of the transparent conductive layer 400 by the reaction ‘ZnO+H₂→Zn+H₂O’.

As shown in FIG. 4(E), a rear electrode material layer 600a is formed on the metal layer 510.

As shown in FIG. 4(F), a rear electrode 600 is formed by baking the rear electrode material layer 600a, and simultaneously a buffer layer 500 comprised of the metal layer 510, and an oxide layer 530 of the metal layer 510 is formed by oxidizing the upper portion of the metal layer 510.

Accordingly, the thin film type solar cell according to the present invention and the method for manufacturing the same has the following advantages.

First, the buffer layer is formed between the transparent conductive layer and the rear electrode, thereby reducing the electric resistance of the rear electrode, and enhancing the adhesive strength between the transparent conductive layer and the rear electrode.

In detail, the buffer layer is formed of the metal material whose oxidization degree is higher than that of the material for the rear electrode. Thus, during the baking process for forming the rear electrode, the oxide of the metal material with small electric resistance is formed instead of the oxide of the material for the rear electrode, whereby the reduced electric resistance of the rear electrode enables the improved efficiency of solar cell. Also, the adhesive strength between the transparent conductive layer and the rear electrode can be enhanced by the oxide of the metal material comprised in the buffer layer.

Also, according as both the transparent conductive layer and the oxide of the metal material comprised in the buffer layer are formed of the same material, steps for forming the both may be performed by continuous processes in the same apparatus.

Also, the metal material of the buffer layer may be formed through the use of the material for the transparent conductive layer, thereby resulting in the simplified manufacturing process.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A thin film type solar cell comprising:
a front electrode formed on a substrate;
a semiconductor layer formed on the front electrode;
a transparent conductive layer formed on the semiconductor layer;
a rear electrode formed over the transparent conductive layer; and
a buffer layer, formed between the transparent conductive layer and the rear electrode, for reducing an electric resistance of the rear electrode and enhancing an adhesive strength between the transparent conductive layer and the rear electrode.

2. The thin film type solar cell of claim 1, wherein the buffer layer comprises a material layer whose oxidization degree is higher than that of the rear electrode.

3. The thin film type solar cell of claim 1, wherein the buffer layer is comprised of a metal layer and an oxide layer deposited in sequence, wherein the metal layer has an oxidization degree which is higher than that of a material for the rear electrode, and the oxide layer is formed of an oxide of the metal layer.

4. The thin film type solar cell of claim 3, wherein the oxide layer comprised in the buffer layer has an electric resistance which is smaller than that of an oxide of the rear electrode.

5. The thin film type solar cell of claim 3, wherein both the transparent conductive layer and the oxide layer comprised in the buffer layer are formed of the same material.

6. The thin film type solar cell of claim 5, wherein both the transparent conductive layer and the oxide layer comprised in the buffer layer are formed of ZnO.

7. A method for manufacturing a thin film type solar cell comprising the steps of:
forming a front electrode on a substrate;
forming a semiconductor layer on the front electrode;
forming a transparent conductive layer on the semiconductor layer;
forming a buffer layer on the transparent conductive layer; and
forming a rear electrode on the buffer layer.

8. The method of claim 7, wherein the step of forming the buffer layer further comprises sequentially forming a metal layer and an oxide layer, wherein the metal layer has an oxidization degree which is higher than that of a material for the rear electrode, and the oxide layer is formed of an oxide of the metal layer.

9. The method of claim 8, wherein the step of forming the rear electrode further comprises of a step for printing a rear electrode material and baking the printed rear electrode material, said oxide layer of the metal layer comprised in the buffer layer being formed by oxidizing the metal layer during baking the printed rear electrode material.

10. The method of claim 8, wherein the metal layer comprised in the buffer layer is formed by depositing an additional layer on the transparent conductive layer.

11. The method of claim 10, wherein the step of forming the metal layer comprised in the buffer layer is comprises forming Zn by sputtering process targeting Zn under an inert-gas atmosphere.

12. The method of claim 11, wherein the step of forming the transparent conductive layer comprises forming ZnO by sputtering process targeting Zn under an oxygen atmosphere; and
said step of forming the transparent conductive layer and the metal layer comprised in the buffer layer are continuously performed in the same sputtering apparatus.

13. The method of claim 10, wherein the step of forming the metal layer comprised in the buffer layer further comprises forming Zn by CVD or ALD using a gaseous material containing Zn under a hydrogen-gas atmosphere.

14. The method of claim 8, wherein the step of forming the metal layer comprised in the buffer layer further comprises deoxidizing an upper portion of the transparent conductive layer.

15. The method of claim 14, wherein the step of deoxidizing the upper portion of the transparent conductive layer further comprises performing a hydrogen plasma treatment so as to react oxygen contained in the transparent conductive layer with hydrogen supplied for the hydrogen plasma treatment.

16. The method of claim 8, wherein the oxide layer of the metal layer comprised in the buffer layer has an electric resistance which is smaller than that of an oxide of the rear electrode.
